(19) United States
(12) Patent Application Publication
(10) Pub. No.: US 2024/0047291 A1
(43) Pub. Date: Feb. 8, 2024

(54) HIGH DENSITY PLASMA CVD FOR DISPLAY ENCAPSULATION APPLICATION

(71) Applicant: Applied Materials, Inc., Santa Clara, CA (US)

(72) Inventors: Tae Kyung WON, San Jose, CA (US); Soo Young CHOI, Fremont, CA (US); Dong Kil YIM, Pleasanton, CA (US); Young Dong LEE, Hwaseong-Si (KR); Zongkai WU, Redwood City, CA (US); Sanjay D. YADAV, Morgan Hill, CA (US)

(21) Appl. No.: 17/641,365

(22) PCT Filed: Sep. 10, 2019
(86) PCT No.: PCT/US2019/050456

§ 371 Date: Mar. 8, 2022

(51) Int. Cl. H01L 23/31; H01L 23/29; H01L 21/56; H01L 21/02; H01L 33/00; H01L 33/56; H01L 21/285

(52) U.S. Cl. CPC H01L 23/3192; H01L 23/291; H01L 21/56; H01L 21/02274; H01L 21/02164; H01L 21/0217; H01L 21/0214; H01L 33/0095; H01L 33/56; H01L 21/285

(57) ABSTRACT

Embodiments of the present disclosure generally relate to moisture barrier films utilized in an organic light emitting diode device. A moisture barrier film is deposited in a high density plasma chemical vapor deposition chamber at a temperature of less than about 250 degrees Celsius, an inductively coupled plasma power frequency of about 2 MHz to about 13.56 MHz or a microwave power frequency of about 2.45 GHz, and a plasma density of about 10¹¹ cm³ to about 10¹² cm³. The moisture barrier film comprises a material selected from the group consisting of silicon oxynitride, silicon nitride, and silicon oxide. The moisture barrier film has a thickness of less than about 3,000 Angstroms, a refractive index between about 1.45 and 1.95, and an absorption coefficient of about zero at UV wavelengths. The moisture barrier film may be utilized in a thin film encapsulation structure or a thin film transistor.

### BACKGROUND

### Field

Embodiments of the present disclosure generally relate to an organic light emitting diode (OLED) device, and more particularly, to moisture barrier films utilized in an OLED device.

### Description of the Related Art

In the manufacture of flat panel displays, many processes are employed to deposit thin films, such as moisture barrier films, on substrates, such as semiconductor substrates, solar panel substrates, liquid crystal display (LCD) and/or OLED substrates, to form electronic devices thereon. The deposition of such thin films is generally accomplished by introducing a precursor gas into a vacuum chamber having a substrate disposed on a temperature controlled substrate support. The precursor gas is typically directed through a gas distribution plate situated near the top of the vacuum chamber. The precursor gas in the vacuum chamber may be energized (e.g., excited) into a plasma by applying a radio frequency (RF) power to a conductive showerhead disposed in the chamber from one or more RF sources coupled to the chamber. The excited gas reacts to form a layer of material on a surface of the substrate.

Often times, a capacitively coupled plasma (CCP) arrangement is used to deposit barrier films on OLED and LCD substrates. Traditionally, the plasma is formed in a conventional chamber utilizing a CCP arrangement for ionizing gas atoms and forming radicals of a deposition gas, which are useful for the deposition of a film layer on substrates. However, barrier films deposited using a CCP arrangement are generally quite thick, having a thickness of about 7,000 angstroms to about 10,000 angstroms, have a non-zero absorption coefficient at ultraviolet (UV) wavelengths, and have a refractive index of greater than 1.7.

Therefore, there is a need for an improved method of depositing barrier films for OLED and LCD structures.

### SUMMARY

Embodiments of the present disclosure generally relate to moisture barrier films utilized in an organic light emitting diode device. A moisture barrier film is deposited in a high density plasma chemical vapor deposition chamber at a temperature of less than about 250 degrees Celsius, an inductively coupled plasma power frequency of about 2 MHz to about 13.56 MHz or a microwave power frequency of about 2.45 GHz, and a plasma density of about 10¹¹ cm³ to about 10¹² cm³. The moisture barrier film comprises a material selected from the group consisting of silicon oxynitride, silicon nitride, and silicon oxide. The moisture barrier film has a thickness of less than about 3,000 Angstroms, a refractive index between about 1.45 and 1.95, and an absorption coefficient of about zero at UV wavelengths. The moisture barrier film may be utilized in a thin film encapsulation structure or a thin film transistor.

A method for depositing a barrier layer comprises placing a substrate in a chemical vapor deposition (CVD) chamber comprising a high density plasma arrangement, and depositing a barrier layer over the substrate using the high density plasma arrangement at a temperature of less than about 250 degrees Celsius, a power frequency of about 2 MHz to about 13.56 MHz, and a plasma density of about 10¹¹ cm³ to about 10¹² cm³.

A thin film encapsulation structure comprises a first barrier layer deposited using a high density plasma CVD chamber, the first barrier layer comprising a material selected from the group consisting of silicon oxynitride, silicon nitride, and silicon oxide, wherein the first barrier layer has a thickness of less than about 3,000 Angstroms, a refractive index between about 1.45 and 1.95, and an absorption coefficient of about zero, a buffer layer disposed on the first barrier layer, and a second barrier layer disposed on the buffer layer.

A method for depositing a barrier layer comprises placing a substrate in a CVD chamber comprising a high density plasma arrangement, and depositing a barrier layer over the substrate using the high density plasma arrangement at a temperature of less than about 250 degrees Celsius, a power frequency of about 2 MHz to about 13.56 MHz, and a plasma density of about 10¹¹ cm³ to about 10¹² cm³, wherein the barrier layer has a thickness of less than about 3,000 Angstroms, a refractive index between about 1.45 and 1.95, and an absorption coefficient of about zero.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic, cross sectional view of a chemical vapor deposition apparatus, according to one embodiment.

FIG. 2 illustrates a high density plasma arrangement, according to one embodiment.

FIG. 3 is a schematic, cross sectional view of a display device having a thin film encapsulation structure disposed thereon, according to one embodiment.

FIG. 4 illustrates a schematic, cross sectional view of a thin film transistor utilized in a display device, according to another embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to moisture barrier films utilized in an organic light emitting diode device. A moisture barrier film is deposited in a high density plasma chemical vapor deposition chamber at a temperature of less than about 250 degrees Celsius, an inductively coupled plasma power frequency of about 2 MHz to about 13.56 MHz or a microwave power frequency of about 2.45 GHz, and a plasma density of about 10¹¹ cm³ to about 10¹² cm³. The moisture barrier film comprises a material selected from the group consisting of silicon oxynitride, silicon nitride, and silicon oxide. The moisture barrier film has a thickness of less than about 3,000 Angstroms, a refractive index between about 1.45 and 1.95, and an absorption coefficient of about zero at UV wavelengths. The moisture barrier film may be utilized in a thin film encapsulation structure or a thin film transistor.

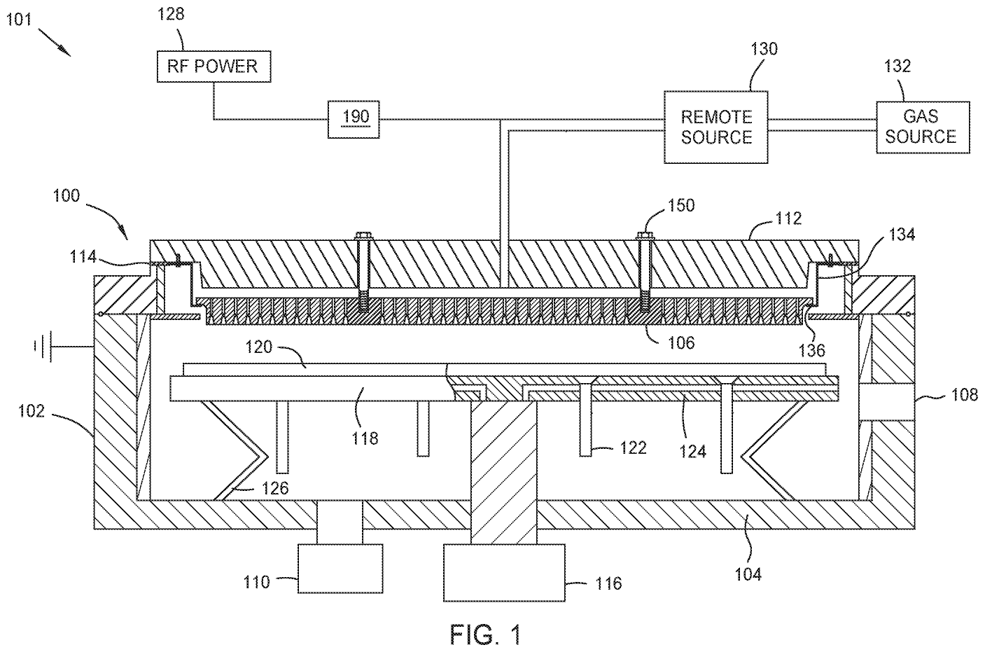

FIG. 1 is a schematic, cross sectional view of a chemical vapor deposition (CVD) apparatus 101 that may be used to perform the operations described herein. The CVD apparatus 101 may be a plasma enhanced CVD apparatus. The CVD apparatus 101 includes a chamber 100 in which one or more films may be deposited onto a substrate 120. The chamber 100 generally includes walls 102, a bottom 104, and a showerhead 106, which collectively define a process volume. The process volume may be a vacuum environment. A substrate support 118 is disposed within the process volume. The process volume is accessed through a slit valve opening 108 such that the substrate 120 may be transferred in and out of the chamber 100. The substrate support 118 may be coupled to an actuator 116 to raise and lower the substrate support 118. Lift pins 122 are moveably disposed through the substrate support 118 to move the substrate 120 to and from the substrate receiving surface. The substrate support 118 also includes heating and/or cooling elements 124 to maintain the substrate support 118 at a desired temperature. The substrate support 118 also includes RF return straps 126 to provide an RF return path at the periphery of the substrate support 118.

The showerhead 106 is coupled to a backing plate 112 by a fastening mechanism 150. The showerhead 106 is coupled to the backing plate 112 by one or more fastening mechanisms 150 to help prevent sag and/or control the straightness/curvature of the showerhead 106.

A gas source 132 is coupled to the backing plate 112 to provide gas through gas passages in the showerhead 106 to a processing area between the showerhead 106 and the substrate 120. A vacuum pump 110 is coupled to the chamber 100 to maintain the process volume at a desired pressure. An RF source 128 is coupled through a match network 190 to the backing plate 112 and/or to the showerhead 106 to provide an RF current to the showerhead 106. The RF current creates an electric field between the showerhead 106 and the substrate support 118 so that a plasma may be generated from the gases between the showerhead 106 and the substrate support 118.

A remote plasma source 130, such as an inductively coupled remote plasma source 130, may also be coupled between the gas source 132 and the backing plate 112. Between processing substrates, a cleaning gas may be provided to the remote plasma source 130 so that a remote plasma is generated. The radicals from the remote plasma may be provided to chamber 100 to clean chamber 100 components. The cleaning gas may be further excited by the RF source 128 provided to the showerhead 106.

The showerhead 106 is additionally coupled to the backing plate 112 by showerhead suspension 134. In one embodiment, the showerhead suspension 134 is a flexible metal skirt. The showerhead suspension 134 has a lip 136 upon which the showerhead 106 may rest. The backing plate 112 may rest on an upper surface of a ledge 114 coupled with the chamber walls 102 to seal the chamber 100 to form the vacuum environment.

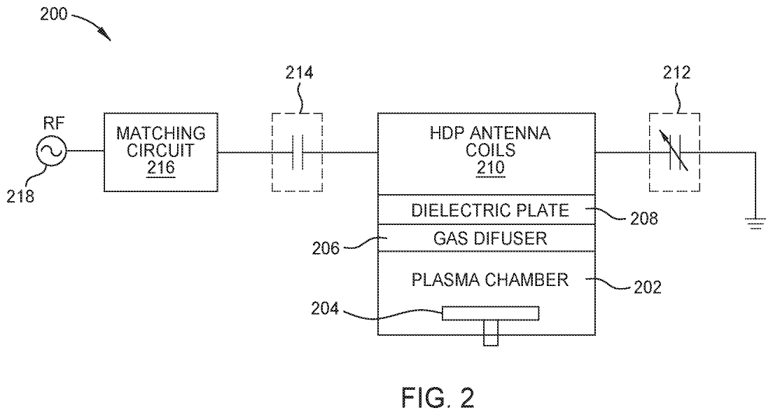

FIG. 2 illustrates a high density plasma (HDP) arrangement 200, according to one embodiment. The HDP arrangement 200 may be utilized with the CVD apparatus 101 of FIG. 1 to form an HDP CVD chamber (i.e., the CVD apparatus 101 comprises the HDP arrangement 200). The HDP arrangement 200 may be an inductively coupled plasma (ICP) arrangement or a microwave (MW) arrangement. The HDP arrangement 200 comprises a substrate support 204 disposed in a plasma chamber 202. A gas diffuser 206 is disposed above the plasma chamber 202, and a dielectric plate 208 is disposed above the gas diffuser 206.

One or more HDP antenna coils 210 are disposed on or over the dielectric plate 208. A terminal capacitor 212 and an intermediate capacitor 214 are coupled to the one or more HDP antenna coils 210. The terminal capacitor 212 may be grounded. The intermediate capacitor 214 is coupled to a power source 218, such as an RF source. The power source 218 includes a match circuit 216 or a tuning capability for adjusting electrical characteristics of the one or more HDP antenna coils 210. For an ICP arrangement, the power frequency may be about 2 MHz to about 13.56 MHz. For an MW arrangement, the power frequency may be between about 2.4 GHZ to about 2.5 GHZ, such as about 2.45 GHz.

The gas diffuser 206 is configured to deliver processes gases to the plasma chamber 202. Each of the one or more HDP antenna coils 210 is configured to create an electromagnetic field that energizes the process gases into a plasma in the plasma chamber 202 below the gas diffuser 206 as gas is flowing into the into the plasma chamber 202 volume therebelow. The plasma then forms one or more films or layers on a substrate disposed on the substrates support 204.

The HDP arrangement 200 is configured to deposit or form HDP CVD films, such as moisture barrier films, on a substrate by using a high plasma density of about 10¹¹ cm³ to about 10¹² cm³ and a low ion bombarding energy of less than about 10² eV, resulting in a high ionization efficiency and low plasma damage. The HDP arrangement 200 can be utilized to form high quality films at low temperatures, such as about less than 250 degrees Celsius, and has a high deposition rate with a low arcing probability. The ion/radical flux and energy of the HDP arrangement 200 is independently controlled by source and bias power. Moreover, utilizing the HDP arrangement 200 to deposit moisture barrier layers enables the moisture barrier layers to have a low RI with a wide range of RI control.

Conversely, CVD films formed or deposited by a CCP arrangement typically have a low plasma density of about 10⁹ cm³ to about 10¹⁰ cm³ and a high ion bombarding energy of greater than about 10² eV, resulting in a low ionization efficiency and high plasma damage. Moreover, films formed by a CCP arrangement have a low quality when deposited at low temperatures, such as about less than 250 degrees Celsius, and the CCP arrangement has a low deposition rate with a high arcing probability. The ion/radical flux and energy of a CCP arrangement is controlled by source power only.

FIG. 3 is a schematic, cross sectional view of a display device 300 having a thin film encapsulation (TFE) structure 314 disposed thereon, according to one embodiment. The display device 300 comprises a substrate 302. The substrate 302 may be made of a silicon-containing material, glass, polyimide, or plastic, such as polyethyleneterephthalate (PET) or polyethylenenaphthalate (PEN). A light emitting device 304 is disposed on the substrate 302. The light emitting device 304 may be an OLED structure or a quantum-dot structure. A contact layer (not shown) may be disposed between the light emitting device 304 and the substrate 302, and the contact layer is in contact with the substrate 302 and the light emitting device 304.

A capping layer 306 is disposed over the light emitting device 304 and the substrate 302. The capping layer 306 may have a refractive index of about 1.7 to about 1.8. A thin metal layer (not shown) may be disposed over the capping layer 306. A first barrier layer 308 is disposed on the capping layer 306 or the thin metal layer. A buffer layer 310 is disposed on the first barrier layer 308. A second barrier layer 312 is disposed on the buffer layer 310. The first barrier layer 308, the buffer layer 310, and the second barrier layer 312 comprise the TFE structure 314. The first barrier layer 308 and the second barrier layer 312 are moisture barrier films or layers.

The buffer layer 310 may comprise an organic material having a refractive index of about 1.5. The buffer layer 310 may comprise organosilicon compounds, such as plasma-polymerized hexamethyldisiloxane (pp-HMDSO), fluorinated plasma-polymerized hexamethyldisiloxane (pp-HM DSO: F), and hexamethyldisilazane (HMDSN). Alternatively, the buffer layer 310 may be a polymer material composed by hydrocarbon compounds. The polymer material may have a formula CₓH_{y}O_{z}, wherein x, y and z are integers. In one embodiment, the buffer layer 310 may be selected from a group consisting of polyacrylate, parylene, polyimides, polytetrafluoroethylene, copolymer of fluorinated ethylene propylene, perfluoroalkoxy copolymer resin, copolymer of ethylene and tetrafluoroethylene, parylene. In one specific example, the buffer layer 310 is polyacrylate or parylene.

The first barrier layer 308 may be deposited in an HDP CVD chamber, such as the CVD apparatus 101 of FIG. 1, utilizing an HDP arrangement, such as the HDP arrangement 200 of FIG. 2. The first barrier layer 308 is comprised of a material selected from the group consisting of silicon nitride (SiN), silicon oxide (SiO), and silicon oxynitride (SiON). Additionally, each layer of the TFE structure 314 may be deposited in an HDP CVD chamber, such as the CVD apparatus 101 of FIG. 1, utilizing an HDP arrangement, such as the HDP arrangement 200 of FIG. 2. Purging of the CVD chamber may be performed between cycles to minimize the risk of contamination.

To deposit the first barrier layer 308 using an ICP HDP arrangement, the power frequency may be about 2 MHz to about 13.56 MHz. To deposit the first barrier layer 308 using an MW HPD arrangement, the power frequency may be between about 2.4 GHZ to about 2.5 GHZ, such as about 2.45 GHz. The first barrier layer is deposited using a high plasma density of about 10¹¹ cm³ to about 10¹² cm³ and a low ion bombarding energy of less than about 10² eV, resulting in a high ionization efficiency and low plasma damage. The first barrier layer 308 is deposited as a high quality film at low temperatures, such as about less than 250 degrees Celsius, and at a high deposition rate with a low arcing probability. In one embodiment when the first barrier layer 308 comprises SiO, the first barrier layer 308 may be deposited at temperature of about 100 degrees Celsius at a rate of about 2000 Angstroms per minute. In another embodiment when the first barrier layer 308 comprises SiN, the first barrier layer 308 may be deposited at temperature of about 100 degrees Celsius at a rate of about 1,000 Angstroms per minute.

Furthermore, depositing the first barrier layer 308 using the HDP arrangement enables the first barrier layer 308 to have a refractive index (RI) of about 1.4 to 2.1 and a low absorption coefficient (k) of about zero, which results in the first barrier layer 308 having a zero or near-zero absorption at UV wavelengths. The first barrier layer 308 deposited using the HDP arrangement further has a thickness of less than about 3,000 Angstroms, such as about less than about 2,000 Angstroms, which reduces barrier thickness requirements, reduces bending/folding stress, and reduces the amount of time required to deposit the first barrier layer 308. Moreover, the HDP arrangement allows the first barrier layer 308 to be easily deposited on sidewalls or as sidewall barriers without causing oxidation, reducing sidewall barrier thickness requirements.

In one embodiment, the first barrier layer 308 comprises SiN, and SiH₄ and NH₃ gases are introduced into the chamber for depositing the SiN first barrier layer 308. For example, about 100 sccm of SiH₄ and about 600 sccm of NH₃ may be used. A chamber pressure of about 120 mTorr, an ICP power frequency of about 2 MHz, a power of about 3,000 W, and a power density of about 1.725 W/cm² may be applied for about 300 seconds.

When utilizing the HDP arrangement, the first barrier layer 308 comprising SiN may have a wet etch rate (WER) of about 325 angstroms per minute, a film density about 2.52 g/cm³, an RI of about 1.91 to about 1.95, a modulus of about 150 GPa to about 160 GPa, a water vapor transmission rate (WVTR) of about 1×10⁻⁴ g/m²/day to about 3×10⁻⁴ g/m²/day at 40 degrees Celsius and 100% humidity to a depth of about 500 angstroms, and XTEM structure that is dense having few voids. In comparison, when utilizing a CCP arrangement, the first barrier layer comprising SiN may have a WER of about 13,660 angstroms per minute, a film density about 2.10 g/cm³, a modulus of about 100 GPa, a WVTR of about less than 1×10⁻⁴ g/m²/day at 40 degrees Celsius and 100% humidity to a depth of about 5,000 angstroms, and XTEM structure that has several spherical voids.

In another embodiment, the first barrier layer 308 comprises SiON, and SiH₄, N₂O, and NH₃ gases are introduced into the chamber for depositing the SiON first barrier layer 308. For example, about 100 sccm of SiH₄, about 200 sccm to about 500 sccm of NH₃, and about 100 sccm to about 400 sccm of N₂O may be used. A chamber pressure of about 120 mTorr, an ICP power frequency of about 2 MHz, a power of about 3,000 W, and a power density of about 1.725 W/cm² may be applied for about 300 seconds.

When utilizing the HDP arrangement, the first barrier layer 308 comprising SiON may have a WER of about 3,000 Angstroms per minute, a film density about 2.13 g/cm³ to about 2.26 g/cm³, an RI of about 1.47 to about 1.84, and a WVTR of about 1×10⁻⁴ g/m²/day to about 7×10⁻⁴ g/m²/day at 40 degrees Celsius and 100% humidity to a depth of about 2,000 angstroms. In comparison, when utilizing a CCP arrangement, the first barrier layer comprising SiON may have a WER of about 20,000 angstroms per minute, a film density about 2.04 g/cm³, and a WVTR of about less than 1×10⁻⁴ g/m²/day at 40 degrees Celsius and 100% humidity to a depth of about 10,000 Angstroms.

In yet another embodiment, the first barrier layer 308 comprises SiO, and SiH₄ and N₂O gases are introduced into the chamber for depositing the SiO first barrier layer 308. For example, about 30 sccm of SiH₄ and about 1,000 sccm of N₂O may be used. A chamber pressure of about 120 mTorr, an ICP power frequency of about 2 MHz, a power of about 4,000 W, and a power density of about 2.300 W/cm² may be applied for about 130 seconds.

When utilizing the HDP arrangement, the first barrier layer 308 comprising SiO may have a WER of about 3,400 Angstroms per minute, a film density about 2.09 g/cm³, an RI of about 1.46, and a WVTR of about 1×10⁻³ g/m²/day at 40 degrees Celsius and 100% humidity to a depth of about 2,000 Angstroms. In comparison, when utilizing a CCP arrangement, the first barrier layer comprising SiO may have a WER of about 20,000 Angstroms per minute and no moisture barrier properties.

The second barrier layer 312 is comprised of a material selected from the group consisting of SiN, SiO, and SiON. The second barrier layer 312 may comprise the same material or a different material than the first barrier layer 308. In some embodiments, the second barrier layer 312 is deposited using the same process and parameters described above using the CVD apparatus 101 of FIG. 1 and the HDP arrangement 200 of FIG. 2. As such, the first barrier layer 308 and/or the second barrier layer 312 deposited using an HDP arrangement at a low temperature are high quality, thin, dense moisture barrier layers having a low RI and a low absorption coefficient of about zero.

In one embodiment, the TFE structure 314 is formed by placing the substrate 302 including the light emitting device 304 into the HDP CVD chamber. The capping layer 306 may be deposited on the light emitting device 304 in the CVD chamber, or the capping layer 306 may already be deposited on the light emitting device when placed into the chamber. The first barrier layer 308 is deposited on the capping layer 306 in the chamber by the process discussed above.

The buffer layer 310 is then deposited over the first barrier layer 308 in the chamber by a CVD process. A purge step is performed after depositing the first barrier layer 308 prior to depositing the buffer layer 310, because different precursors are being used for the deposition processes. After the buffer layer 310 is deposited, another purge step is performed. The second barrier layer 312 is deposited over the buffer layer 310, and the second barrier layer 312 may be deposited under the same process conditions as the first barrier layer 308.

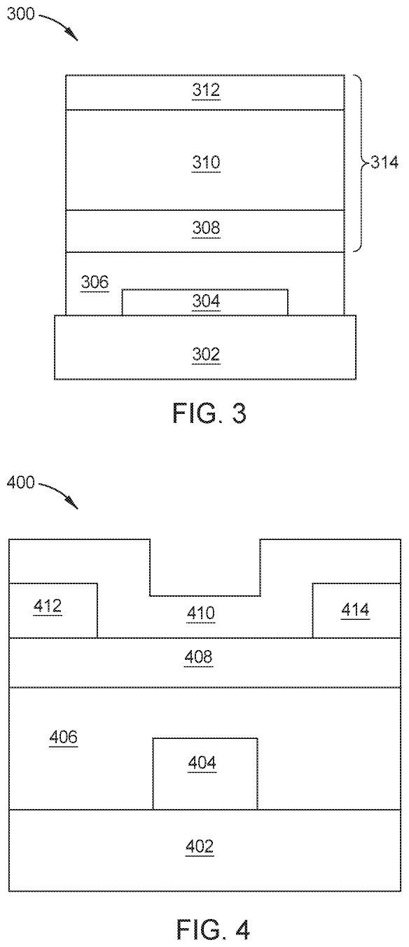

FIG. 4 is a schematic, cross sectional view of a thin film transistor (TFT) 400 utilized in a display device, according to various embodiments. The TFT 400 may be a metal oxide TFT. The TFT 400 comprises a substrate 402. The substrate 402 may be made of a silicon-containing material, glass, polyimide, or plastic, such as PET or PEN. A gate electrode 404 is disposed on the substrate 402. The gate electrode 404 may comprise copper, tungsten, tantalum, aluminum, among others. A gate insulating layer 406 is disposed over the gate electrode 404 and the substrate 402.

A semiconductor layer 408 is disposed over the gate insulating layer 406. The semiconductor layer 408 may comprise a metal oxide semiconductor material, a metal oxynitride semiconductor material, such as indium gallium zinc oxide (IGZO), or silicon, such as amorphous silicon, crystalline silicon, and polysilicon, among others. A drain electrode 412 and a source electrode 414 are disposed on the semiconductor layer 408. The drain electrode 412 is spaced from and adjacent to the source electrode 414. The drain electrode 412 and the source electrode 414 may each comprise copper, tungsten, tantalum, aluminum, among others. A passivation layer 410 is disposed over the semiconductor layer 408, the drain electrode 412, and the source electrode 414. The passivation layer 410 and the gate insulating layer 406 are moisture barrier films or layers.

The passivation layer 410 and the gate insulating layer 406 may each be deposited in an HDP CVD chamber, such as the CVD apparatus 101 of FIG. 1, utilizing an HDP arrangement, such as the HDP arrangement 200 of FIG. 2. The gate insulating layer 406 is deposited first, followed by the semiconductor layer 408, followed by the passivation layer 410. The passivation layer 410 and the gate insulating layer 406 may each individually comprise the same material as the first barrier layer 308 of FIG. 3. The passivation layer 410 and the gate insulating layer 406 may each be comprised of a material selected from the group consisting of SiN, SiO, and SiON. The chamber may be purged between each layer deposition.

The passivation layer 410 and the gate insulating layer 406 may each be deposited on a substrate using a high plasma density of about 10¹¹ cm³ to about 10¹² cm³ and a low ion bombarding energy of less than about 10² eV, resulting in a high ionization efficiency and low plasma damage. For an ICP HPD arrangement, the power frequency may be about 2 MHz to about 13.56 MHz. For an MW HPD arrangement, the power frequency may be between about 2.4 GHZ to about 2.5 GHZ, such as about 2.45 GHz. The passivation layer 410 and the gate insulating layer 406 are each deposited as a high quality, dense film at low temperatures, such as about less than 250 degrees Celsius. In one embodiment when the passivation layer 410 and/or the gate insulating layer 406 comprise SiO, the passivation layer 410 and/or the gate insulating layer 406 may be deposited at temperature of about 130 degrees Celsius at a rate of about 2,000 Angstroms per minute. In another embodiment when the passivation layer 410 and/or the gate insulating layer 406 comprise SiN, the passivation layer 410 and/or the gate insulating layer 406 may be deposited at temperature of about 130 degrees Celsius at a rate of about 1000 Angstroms per minute.

Furthermore, depositing the passivation layer 410 and/or the gate insulating layer 406 using the HDP arrangement enables the passivation layer 410 and/or the gate insulating layer 406 to have a refractive index of about 1.4 to 2.1 and a low absorption coefficient (k) of about zero, which results in the passivation layer 410 and/or the gate insulating layer 406 having a zero or near-zero absorption at UV wavelengths. The passivation layer 410 and/or the gate insulating layer 406 deposited using the HDP arrangement each have a thickness of less than about 3,000 Angstroms, such as about less than about 2,000 Angstroms, which reduces barrier thickness requirements, reduces bending/folding stress, and reduces the amount of time required to deposit the passivation layer 410 and/or the gate insulating layer 406. Moreover, the HDP arrangement allows the passivation layer 410 and/or the gate insulating layer 406 to be easily deposited on sidewalls or as sidewall barriers without causing oxidation, reducing sidewall barrier thickness requirements.

In one embodiment, the passivation layer 410 and/or the gate insulating layer 406 comprise SiN, and SiH₄ and NH₃ gases are introduced into the chamber for depositing the SiN passivation layer 410 and/or the SiN gate insulating layer 406. For example, about 100 sccm of SiH₄ and about 600 sccm of NH₃ may be used. A chamber pressure of about 120 mTorr, an ICP power frequency of about 3,000 MHz, and a power density of about 1.725 W/cm² may be applied for about 300 seconds.

When utilizing the HDP arrangement, the passivation layer 410 and/or the gate insulating layer 406 comprising SiN may have a WER of about 325 Angstroms per minute, a film density about 2.52 g/cm³, an RI of about 1.91 to about 1.95, a modulus of about 150 GPa to about 160 GPa, a WVTR of about 1×10⁻⁴ g/m²/day to about 3×10⁻⁴ g/m²/day at 40 degrees Celsius and 100% humidity to a depth of about 500 Angstroms, and XTEM structure that is dense having few voids. In comparison, when utilizing a CCP arrangement, the passivation layer and/or the gate insulating layer comprising SiN may have a WER of about 13,660 angstroms per minute, a film density about 2.10 g/cm³, a modulus of about 100 GPa, a WVTR of about less than 1×10−4 g/m²/day at 40 degrees Celsius and 100% humidity to a depth of about 5000 Angstroms, and XTEM structure that has several spherical voids.

In another embodiment, the passivation layer 410 and/or the gate insulating layer 406 comprise SiON, and SiH₄, N₂O, and NH₃ gases are introduced into the chamber for depositing the SiON passivation layer 410 and/or the SiON gate insulating layer 406. For example, about 100 sccm of SiH₄, about 200 sccm to about 500 sccm of NH₃, and about 100 sccm to about 400 sccm of N₂O may be used. A chamber pressure of about 120 mTorr, an ICP power frequency of about 3,000 MHz, and a power density of about 1.725 W/cm² may be applied for about 300 seconds.

When utilizing the HDP arrangement, the passivation layer 410 and/or the gate insulating layer 406 comprising SiON may have a WER of about 3,000 Angstroms per minute, a film density about 2.13 g/cm³ to about 2.26 g/cm³, an RI of about 1.47 to about 1.84, and a WVTR of about 1×10⁻⁴ g/m²/day to about 7×10⁻⁴ g/m²/day at 40 degrees Celsius and 100% humidity to a depth of about 2,000 Angstroms. In comparison, when utilizing a CCP arrangement, the passivation layer and/or the gate insulating layer comprising SiON may have a WER of about 20,000 Angstroms per minute, a film density about 2.04 g/cm³, and a WVTR of about less than 1×10⁻⁴ g/m²/day at 40 degrees Celsius and 100% humidity to a depth of 10,000 Angstroms.

In yet another embodiment, the passivation layer 410 and/or the gate insulating layer 406 comprise SiO, and SiH₄ and N₂O gases are introduced into the chamber for depositing the SiO passivation layer 410 and/or the SiO gate insulating layer 406. For example, about 30 sccm of SiH₄ and about 1,000 sccm of N₂O may be used. A chamber pressure of about 120 mTorr, an ICP power frequency of about 4,000 MHz, and a power density of about 2.300 W/cm² may be applied for about 130 seconds.

When utilizing the HDP arrangement, the passivation layer 410 and/or the gate insulating layer 406 comprising SiO may have a WER of about 3,400 Angstroms per minute, a film density about 2.09 g/cm³, an RI of about 1.46, and a WVTR of about 1×10⁻³ g/m²/day at 40 degrees Celsius and 100% humidity to a depth of about 2,000 Angstroms. In comparison, when utilizing a CCP arrangement, the passivation layer and/or the gate insulating layer comprising SiO may have a WER of about 20,000 Angstroms per minute and no moisture barrier properties.

The TFE structure 314 and the TFT 400 are two exemplary applications of depositing high quality, thin, dense moisture barrier films at low temperatures using an HDP arrangement. Other applications include moisture barrier layers for touch screen panels, touch sensors, poly imide/colorless poly imide (PI/CPI), hole in active area (HIAA), and low temperature poly silicon (LTPS), among others. As such, high quality, thin, dense barrier films having a low RI and a low or zero absorption coefficient at UV wavelengths can be deposited at low temperatures using an HDP arrangement. Thinner barrier films reduce barrier thickness requirements, reduce bending/folding stress, and reduce the amount of time required to deposit the barrier layer. Barrier layers having a low optical absorption and a low RI with a wide range of RI control can increase light luminance efficiency of displays.

While the foregoing is directed to embodiments of the present disclosure, other and further embodiments of the disclosure may be devised without departing from the basic scope thereof, and the scope thereof is determined by the claims that follow.

1. A method for depositing a barrier layer, comprising:
placing a substrate in a chemical vapor deposition (CVD) chamber comprising a high density plasma arrangement; and
depositing the barrier layer over the substrate using the high density plasma arrangement at a temperature of less than about 250 degrees Celsius, a power frequency of about 2 MHz to about 13.56 MHz, and a plasma density of about 10¹¹ cm³ to about 10¹² cm³.

2. The method of claim 1, wherein the barrier layer is a first barrier layer or a second barrier layer of a thin film encapsulation structure.

3. The method of claim 1, wherein the barrier layer is a passivation layer of a thin film transistor.

4. The method of claim 1, wherein the barrier layer is a gate insulation layer of a thin film transistor.

5. The method of claim 1, wherein the barrier layer is deposited using an inductively coupled plasma power frequency of about 2 MHz to about 13.56 MHz.

6. The method of claim 1, wherein the barrier layer is deposited using a microwave power frequency of about 2 GHz to about 3 GHz.

7. The method of claim 1, wherein the barrier layer comprises a material selected from the group consisting of silicon oxynitride, silicon nitride, and silicon oxide, and wherein the barrier layer has a thickness of less than about 3,000 Angstroms, a refractive index between about 1.45 and 1.95, and an absorption coefficient of about zero.

8. A thin film encapsulation structure, comprising:
a first barrier layer deposited using a high density plasma CVD chamber, the first barrier layer comprising a material selected from the group consisting of silicon oxynitride, silicon nitride, and silicon oxide, wherein the first barrier layer has a thickness of less than about 3,000 Angstroms, a refractive index between about 1.45 and 1.95, and an absorption coefficient of about zero;
a buffer layer disposed on the first barrier layer; and
a second barrier layer disposed on the buffer layer.

9. The thin film encapsulation structure of claim 8, wherein the first barrier layer comprises silicon nitride and has a refractive index between about 1.91 and about 1.95.

10. The thin film encapsulation structure of claim 8, wherein the second barrier layer comprises silicon nitride and has a refractive index between about 1.91 and about 1.95.

11. The thin film encapsulation structure of claim 8, wherein the first barrier layer or the second barrier layer comprises silicon oxynitride and has a refractive index between about 1.47 and about 1.84.

12. The thin film encapsulation structure of claim 8, wherein the first barrier layer or the second barrier layer comprises silicon oxide and has a refractive index of about 1.46.

13. The thin film encapsulation structure of claim 8, wherein the second barrier layer is deposited using the high density plasma CVD chamber, the second barrier layer comprising a material selected from the group consisting of silicon oxynitride, silicon nitride, and silicon oxide.

14. The thin film encapsulation structure of claim 13, wherein the second barrier layer has a thickness of less than about 3,000 Angstroms, a refractive index between about 1.45 and 1.95, and an absorption coefficient of about zero.

15. A method for depositing a barrier layer, comprising:
placing a substrate in a CVD chamber comprising a high density plasma arrangement; and
depositing the barrier layer over the substrate using the high density plasma arrangement at a temperature of less than about 250 degrees Celsius, an inductively coupled plasma power frequency of about 2 MHz to about 13.56 MHz, and a plasma density of about 10¹¹ cm³ to about 10¹² cm³, wherein the barrier layer has a thickness of less than about 3,000 Angstroms, a refractive index between about 1.45 and 1.95, and an absorption coefficient of about zero.

16. The method of claim 15, wherein the barrier layer comprises a material selected from the group consisting of silicon oxynitride, silicon nitride, and silicon oxide.

17. The method of claim 15, wherein the barrier layer is deposited over a light emitting device.

18. The method of claim 15, wherein the barrier layer is a first barrier layer or a second barrier layer of a thin film encapsulation structure.

19. The method of claim 15, wherein the barrier layer is a passivation layer of a thin film transistor.

20. The method of claim 15, wherein the barrier layer is a gate insulation layer of a thin film transistor.
